(19) United States
(12) Patent Application Publication
(10) Pub. No.: US 2014/0321495 A1
(43) Pub. Date: Oct. 30, 2014

(54) INTEGRATED SUB-WAVELENGTH GRATING ELEMENT

(71) Applicants: David A. Fattal, Mountain View, CA (US); Raymond G. Beausoleil, Redmond, WA (US); Marco Fiorentino, Mountai View, CA (US); Paul Kessler Rosenberg, Sunnyvale, CA (US); Terrel Morris, Garland, TX (US)

(72) Inventors: David A. Fattal, Mountain View, CA (US); Raymond G. Beausoleil, Redmond, WA (US); Marco Fiorentino, Mountai View, CA (US); Paul Kessler Rosenberg, Sunnyvale, CA (US); Terrel Morris, Garland, TX (US)

(73) Assignee: HEWLETT-PACKARD DEVELOPMENT COMPANY, L.P., Houston, TX (US)

(21) Appl. No.: 14/364,725

(22) PCT Filed: Jan. 18, 2012
(86) PCT No.: PCT/US2012/021714

§ 371 Date: Jun. 12, 2014

(51) Int. Cl. H01S 5/183; G02B 5/18

(52) U.S. Cl. CPC H01S 5/183; G02B 5/1809; G02B 5/1819; G02B 5/1857
USPC 372/102; 359/576; 359/575; 216/24; 427/58

(57) ABSTRACT

An integrated sub-wavelength grating element includes a transparent layer formed over an optoelectronic substrate layer and a sub-wavelength grating element formed into a grating layer disposed on said transparent layer. The sub-wavelength grating element is formed in alignment with an active region of an optoelectronic component within the optoelectronic substrate layer. The sub-wavelength grating element affects light passing between said grating element and said active region. A method for forming an integrated sub-wavelength grating element is also provided.

### BACKGROUND

Optical engines are commonly used to transfer electronic data at high rates of speed. An optical engine includes hardware for transferring an electrical signal to an optical signal, transmitting that optical signal, receiving the optical signal, and transforming that optical signal back into an electrical signal. The electrical signal is transformed into an optical signal when the electrical signal is used to modulate an optical source device such as a laser. The light from the source is then coupled into an optical transmission medium such as an optical fiber. After traversing an optical network through various optical transmission media and reaching its destination, the light is coupled into a receiving device such as a detector. The detector then produces an electrical signal based on the received optical signal for use by digital processing circuitry.

Circuitry that makes use of optical engines is often referred to as photonic circuitry. The various components that comprise a photonic circuit may include optical waveguides, optical amplifiers, lasers, and detectors. One common component used in photonic circuitry is a Vertical Cavity Surface Emitting Laser (VCSEL). Typically, multiple VCSELs are formed into a single chip and serve as light sources for optical transmission circuits. The light emitted by a VCSEL is typically focused into an optical transmission medium using a system of lenses. Additionally, light detection devices such as photo-detectors are often formed within the chip. Systems of lenses are also used to direct light towards those light detection devices. However, manufacturing and aligning such lens systems is an intricate process that is both costly and time consuming.

### BRIEF DESCRIPTION OF THE DRAWINGS

The accompanying drawings illustrate various examples of the principles described herein and are a part of the specification. The drawings are merely examples and do not limit the scope of the claims.

FIG. 1 is a diagram showing an illustrative optical system, according to one example of principles described herein.

FIGS. 2A and 2B are cross-sectional diagrams showing the formation of an integrated sub-wavelength grating element, according to one example of principles described herein.

FIG. 3 is a diagram showing an illustrative sub-wavelength grating element, according to one example of principles described herein.

FIG. 4 is a cross-sectional diagram showing an illustrative integrated sub-wavelength grating element for collimating light, according to one example of principles described herein.

FIG. 5 is a cross-sectional diagram showing an illustrative integrated sub-wavelength grating element for collimating light at an angle, according to one example of principles described herein.

FIG. 6 is a cross-sectional diagram showing an illustrative integrated sub-wavelength grating element for splitting an incident beam into two collimated beams that are projected in two precise directions, according to one example of principles described herein.

FIG. 7 is a diagram showing an illustrative stacked integrated sub-wavelength grating element, according to one example of principles described herein.

FIG. 8 is a diagram showing an illustrative integrated circuit chip having multiple sub-wavelength gratings for multiple optoelectronic components, according to one example of principles described herein.

FIG. 9 is a flowchart showing an illustrative method for forming an integrated sub-wavelength grating element, according to one example of principles described herein.

Throughout the drawings, identical reference numbers designate similar, but not necessarily identical, elements.

### DETAILED DESCRIPTION

As mentioned above, multiple optoelectronic components such as VCSELs and photo-detectors are typically formed into a single chip and serve as light sources or receivers for optical transmission circuits. In the case of the optoelectronic component being a VCSEL, the light emitted by the VCSEL is then focused into an optical transmission medium using a system of lenses. However, manufacturing and aligning such lens systems is an intricate process that is both costly and time consuming.

In light of this and other issues, the present specification discloses methods and systems for optical elements that are integrated onto the chip in which the optoelectronic components are formed. Optical elements refer to elements which affect the propagation of light such as a grating element. According to certain illustrative examples, a transparent layer (i.e. an oxide layer) is deposited on top of the substrate with the optoelectronic components formed thereon. A grating layer is then formed on top of this transparent layer. Sub-wavelength grating elements can then be formed into this grating layer at the appropriate positions so that those sub-wavelength grating elements are aligned with the active regions of the optoelectronic components. The active region refers to the portion of the optoelectronic component which transmits or detects light.

A sub-wavelength grating element is one in which the spacing between gratings is less than the wavelength of light passing through the grating element. A sub-wavelength grating element can be designed to mimic the behavior of traditional lenses. Specifically, light may be collimated, focused, split, bent, and redirected as desired. Furthermore, due to the planar nature of the sub-wavelength grating elements, additional transparent layers with additional grating layers may be stacked to allow more control over the light emitted from the VCSELs.

Through use of methods and systems embodying principles described herein, optical elements can be manufactured directly onto an integrated circuit chip having optoelectronic components formed thereon. Thus, light emitting from the optoelectronic components such as VCSELs can be focused into various optical transmission mediums or be configured for free space propagation without the use of complicated and costly lens alignment procedures. Additionally, light may be focused onto optoelectronic components such as photo-detectors without such costly lens alignment procedures.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an example” or similar language means that a particular feature, structure, or characteristic described in connection with that example is included as described, but may not be included in other examples.

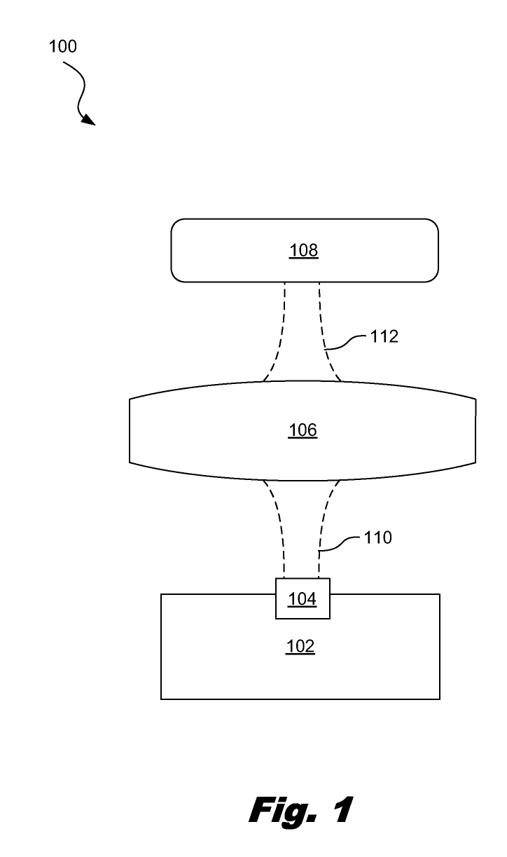

Referring now to the figures, FIG. 1 is a diagram illustrating an optical system (100). According to certain illustrative examples, the optical system (100) includes an optoelectronic component (102). The optoelectronic component may be either a source device such as a VCSEL or a light receiving device such as a photo-detector. A lens system (106) is typically used to couple light (110, 112) between the optoelectronic component (102) and an optical transmission medium (108).

For example, in the case that the optoelectronic component is a VCSEL, the active region (104) projects light (110) into the lens system (106). The lens system (106) may include a number of lenses which are designed to affect light in a predetermined manner. Specifically, the lens system (106) focuses the light (112) into the optical transmission medium (108) based on a variety of factors including the curvature of the lenses within the system, the distances between the lenses, and the nature of the optoelectronic component (102). Use of the lens system (106) involves precise placement of the lens system between the optoelectronic component (102) and the optical transmission medium (108). This precision complicates the manufacturing process and thus adds to the cost.

In light of this issue, the present specification discloses methods and systems for manufacturing optical elements that can be integrated directly onto a chip in a monolithic manner. Thus, the chip itself includes the optical elements that are used to focus light according to the design purposes of the chip. Throughout this specification and in the appended claims, the term “sub-wavelength grating element” is to be interpreted as an optical element wherein the size of the grating features are less than the wavelength of light to pass through the grating element.

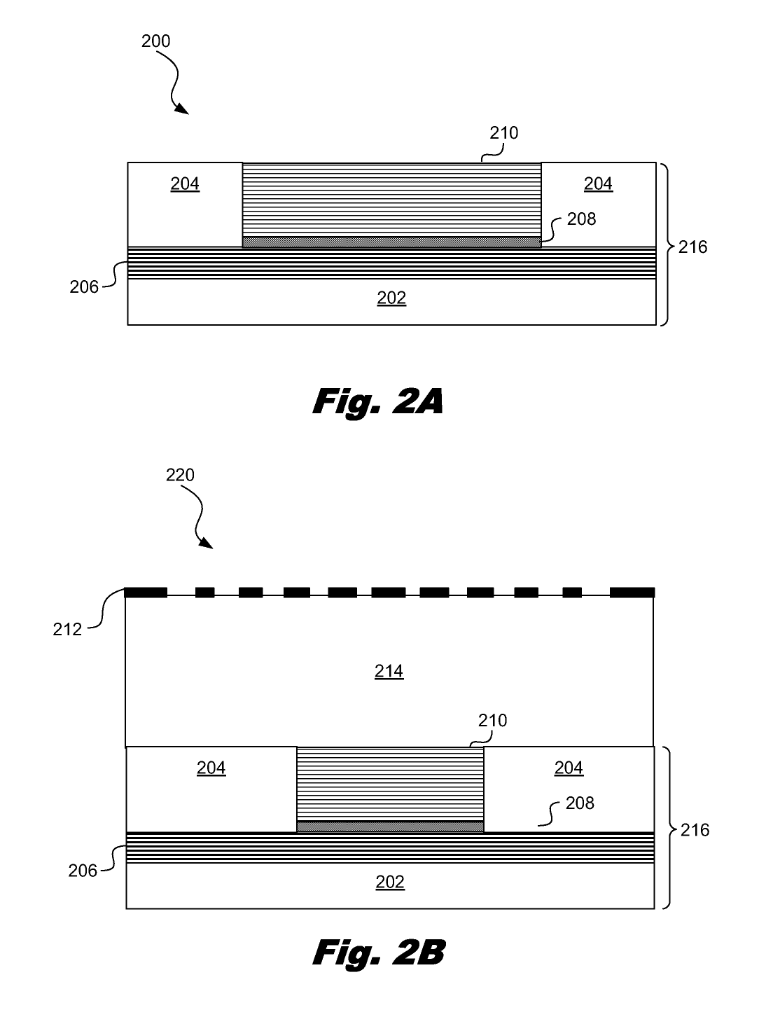

FIGS. 2A and 2B are cross-sectional diagrams showing the formation of an integrated grating element. FIG. 2A is a cross-sectional diagram (200) of a VCSEL formed into an optoelectronic substrate (216). An optoelectronic substrate (216) is part of the integrated circuit chip in which a number of optoelectronic components such as VCSELs or photo-detectors are formed. According to certain illustrative examples, a VCSEL formed within the optoelectronic substrate (216) includes a number of n-type Bragg reflectors (206) formed onto an n-type semiconductor base layer (202).

A number of p-type Bragg reflectors (210) are then formed above the n-type Bragg reflectors (206) with a quantum well (208) between. The p-type Bragg reflectors (210) are formed within an additional substrate layer (204). When a set of metal contacts (not shown) are used to apply an electrical current between the p-type Bragg reflectors (210) and the n-type Bragg reflectors (206), light is emitted from the quantum well (208) of the VCSEL in a direction perpendicular to the optoelectronic substrate (200). By modulating that electrical signal, a modulated beam of light may be used to carry the signal through the emitted beam of light.

FIG. 2B is a diagram showing an illustrative cross-sectional view (220) of the optoelectronic substrate (216) having a sub-wavelength grating element formed thereon. According to certain illustrative examples, a transparent layer (214) is formed directly on top of the VCSEL substrate. The transparent layer (210) may be made of an oxide material. The transparent layer (214) may also act as a planarizing layer. Specifically, as a result of the manufacturing process, different regions of the optoelectronic substrate (216) may be on different planes. For example, the locations of the optoelectronic substrate (216) where VCSELS are formed may be on a different plane in comparison to other regions of the optoelectronic substrate (216).

A grating layer (212) is then formed on top of the transparent layer (214). Through various manufacturing processes such as etching, holes in the grating layer are formed in a particular pattern so as to create a sub-wavelength grating element. By non-periodically varying the dimensions and spacing of the grating features, a sub-wavelength grating element may be designed to act as a lens. For example, the sub-wavelength grating element may be designed to collimate light emanating from the VCSEL. Alternatively, the sub-wavelength grating element may be configured to focus light. In addition to collimating the light, the sub-wavelength grating element may be designed to split the emitted light beam from the VCSELs and redirect each sub-beam in a specific direction.

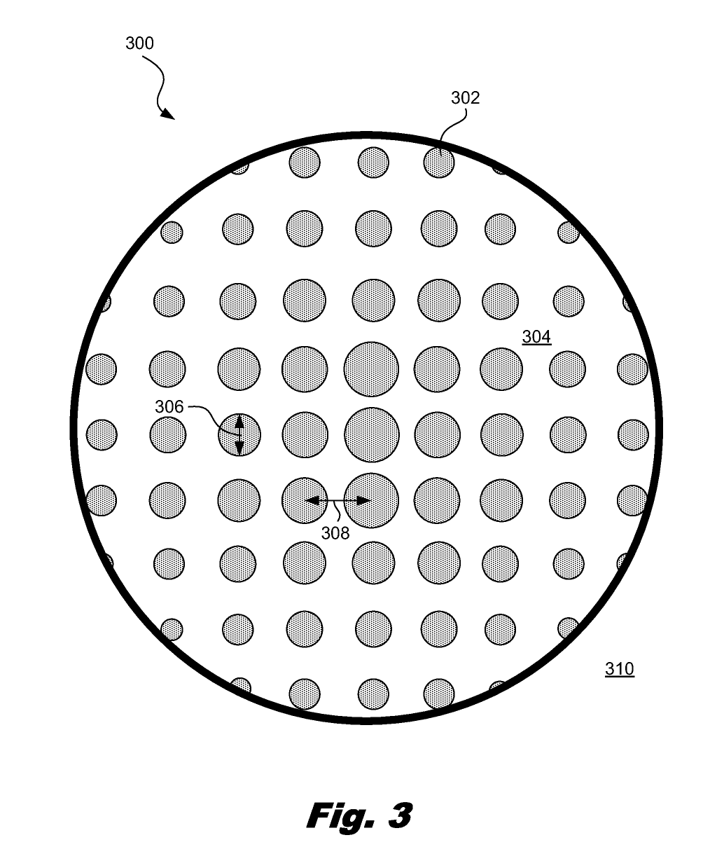

FIG. 3 is a diagram showing an illustrative top view of a sub-wavelength grating element (300). According to certain illustrative examples, the sub-wavelength grating element (300) is a two dimensional pattern formed into the grating layer (310). The grating layer (310) may be composed of a single elemental semiconductor such as silicon or germanium. Alternatively, the grating layer may be made of a compound semiconductor such as a III-V semiconductor. The Roman numerals III and V represent elements in the IIIa and Va columns of the Periodic Table of the Elements.

As mentioned above, the grating layer (310) is formed on top of the transparent layer (e.g. 210, FIG. 2). The grating layer (310) material can be selected so that it has a higher refractive index than the underlying transparent layer. Due to this relatively high difference in refractive index between the grating layer and the transparent layer, the sub-wavelength grating element can is referred to as a high-contrast sub-wavelength grating element.

The grating patterns can be formed into the grating layer (310) to form the sub-wavelength grating elements using Complementary Metal Oxide Semiconductor (CMOS) compatible techniques. For example, a sub-wavelength grating element (300) can be fabricated by depositing the grating layer (310) on a planar surface of the transparent layer using wafer bonding or chemical or physical vapor deposition. Photolithography techniques may then be used to remove portions of the grating layer (310) to expose the transparent layer (304) underneath. Removing portions of the grating layer (310) will leave a number of grating features (302). In the example of FIG. 3, the grating features (302) are posts. However, in some cases, the grating features may be grooves.

The distance between the centers of the grating features (302) is referred to as the lattice constant (308). The lattice constant (308) is selected so that the sub-wavelength grating element does not scatter light in an unwanted manner. Unwanted scattering can be prevented by selecting the lattice constant appropriately. The sub-wavelength grating may also be non-periodic. That is, the parameters of the grating features such as the diameter of the posts or the width of the grooves may vary across the area of the sub-wavelength grating element (300). Both the dimensions (306) of the grating features (302) and the length of the lattice constant (308) are less than the wavelength of light produced by the VCSELs that travels through the sub-wavelength grating element.

The lattice constant (308) and grating feature parameters can be selected so that the sub-wavelength grating element (300) can be made to perform a specific function. For example, the sub-wavelength grating element (300) may be designed to focus light in a particular manner. Alternatively, the sub-wavelength grating element (300) may be designed to collimate light. Additionally, the sub-wavelength grating element may tilt the collimated beam at a specific angle. In some cases, the sub-wavelength grating element may split or bend a beam of light. More detail about sub-wavelength grating elements can be found at, for example, U.S. Patent Publication No. 2011/0261856, published on Oct. 27, 2011.

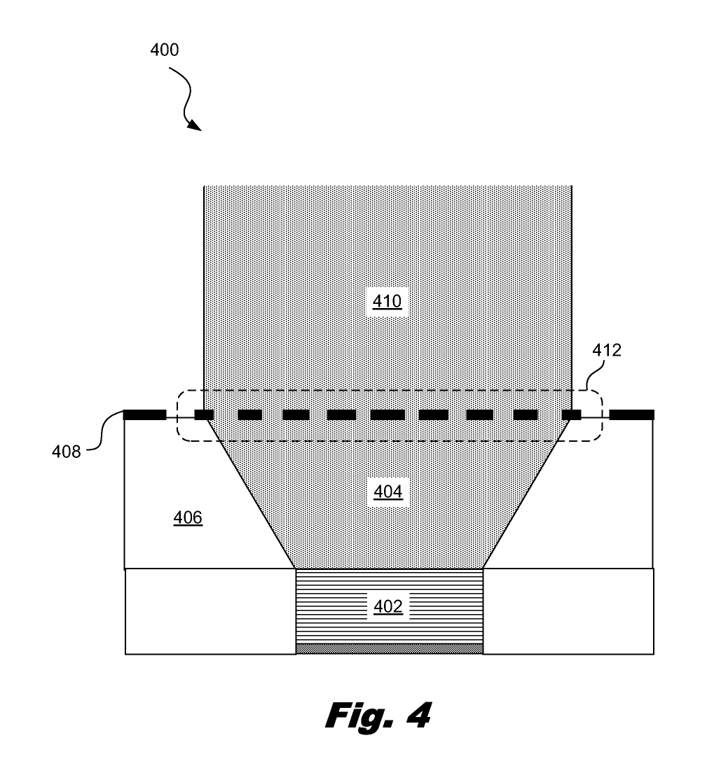

FIG. 4 is a cross-sectional diagram showing an illustrative integrated grating element (400) for collimating light. According to certain illustrative examples, light emitted from the active region (402) of the optoelectronic component (i.e. a VCSEL) is projected through the transparent layer (406) towards the sub-wavelength grating element (412). The sub-wavelength grating element (412) is formed within the grating layer (408) directly over the active region (402). As the light (404) projected from the VCSEL passes through the sub-wavelength grating element, it becomes collimated (410). The collimated light (410) then propagates as normal through free space or any other optical transmission medium placed up against the grating layer (408).

Alternatively, the optoelectronic component may be a source device. In this case, a photo-detector is formed within the surface of the integrated circuit chip. The active region of the photo-detector is the material that detects the light and creates an alternating electrical signal based on the modulation of the light impinging on the photo-detector. In such a case, the sub-wavelength grating element (412) may be designed to receive collimated light and focus that light through the transparent layer (406) onto the active region (402) of the photo-detector.

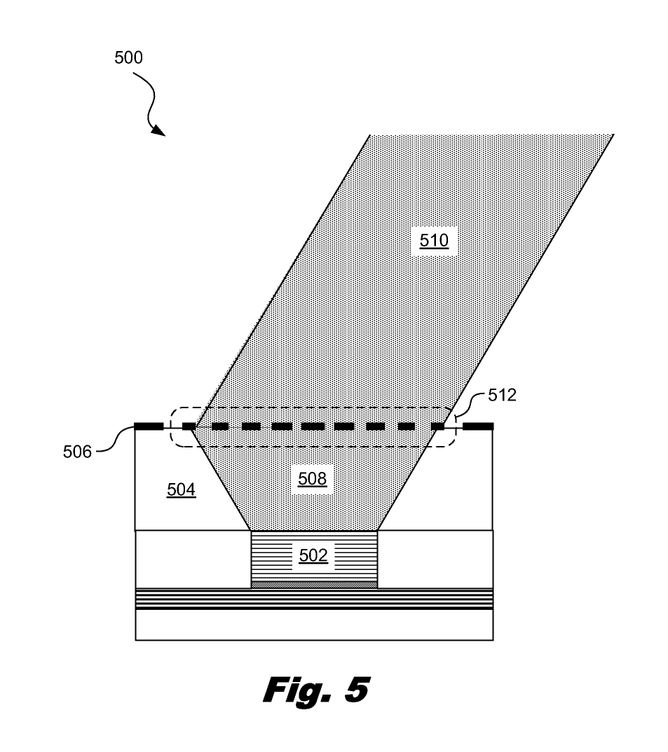

FIG. 5 is a cross-sectional diagram showing an illustrative integrated sub-wavelength grating element (500) for collimating light at an angle. According to certain illustrative examples, light emitted from the active region (502) of the optoelectronic component is projected through the transparent layer (504) towards the sub-wavelength grating element (512). The sub-wavelength grating element (512) is formed within the grating layer (506) directly over the active region (502). As the light (508) projected from the VCSEL passes through the sub-wavelength grating element (512), it becomes collimated (510). Additionally, the collimated light (510) is redirected at a different angle. The collimated, angled light (510) then propagates as normal through free space or any other optical transmission medium placed up against the grating layer (506).

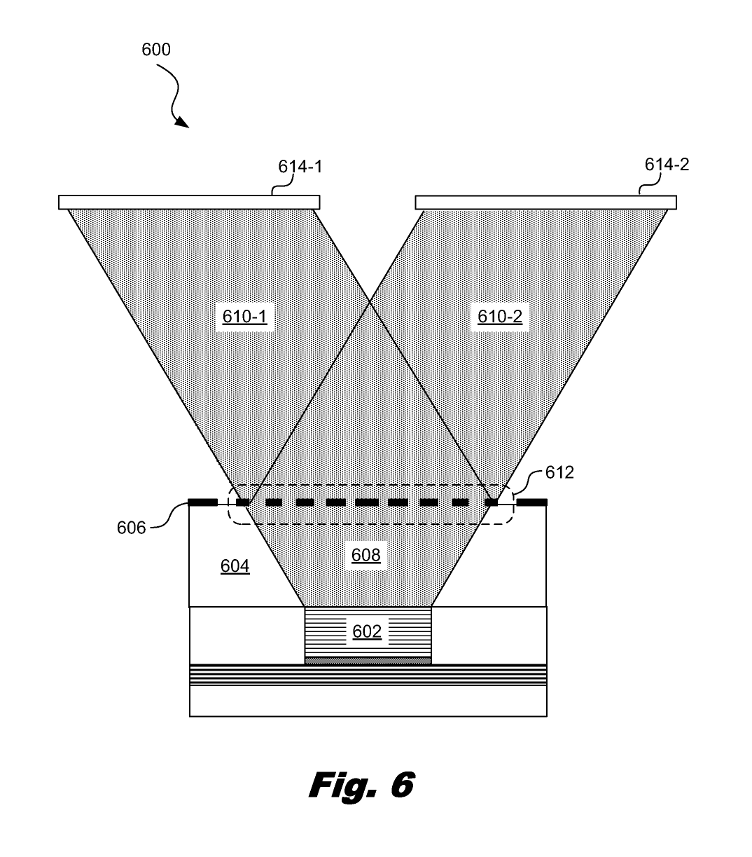

FIG. 6 is a cross-sectional diagram showing an illustrative integrated sub-wavelength grating element (600) splitting an incident beam into two collimated beams that are projected in two precise directions. According to certain illustrative examples, light emitted from the active region (602) of the optoelectronic component (i.e. a VCSEL) is projected through the transparent layer (604) towards the sub-wavelength grating element (612). The sub-wavelength grating element (612) is formed within the grating layer (608) directly over the active region (602). As the light (608) projected from the VCSEL passes through the sub-wavelength grating element (612), it becomes collimated (610). Additionally, the collimated light (610) is redirected at multiple angles. The collimated, angled light (610) then propagates as normal through free space or any other optical transmission medium placed up against the grating layer (606).

One beam of light (610-1) propagates at a first angle while another beam of light (610-2) propagates at a different angle. This effectively duplicates the optical signal that can be carried by the light being emitted from the active region (602). Each of the beams may be precisely directed towards a target spot (614). For example, the first beam of light (610-2) may be projected towards a first target spot (614-1) while the second beam of light (610-2) is projected towards a second target spot (614-2). A target spot (614) may be an additional sub-wavelength grating element to focus or redirect the angled, collimated light (610). In some cases, the collimated beam of light (610) may be split into more than two beams.

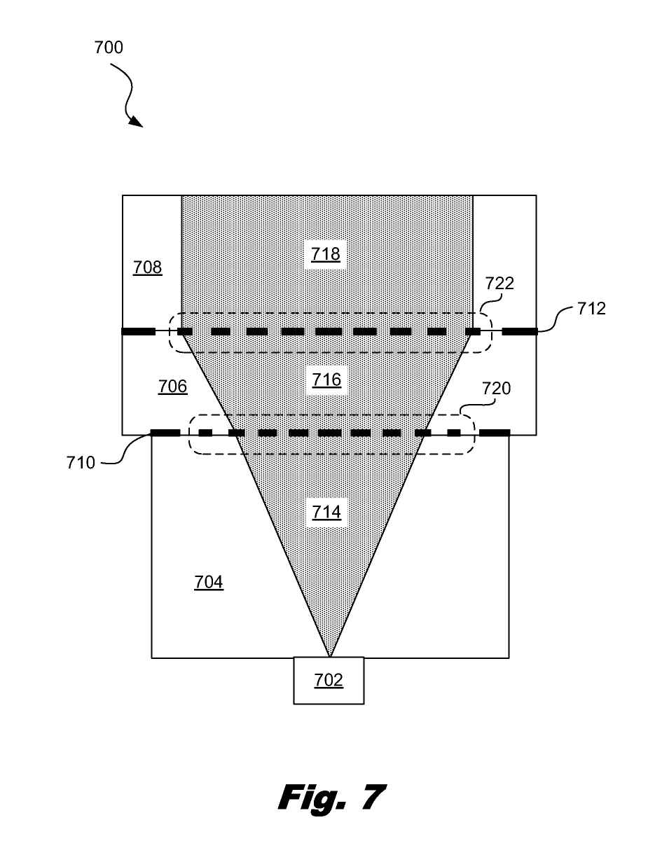

FIG. 7 is a diagram showing an illustrative stacked integrated grating element (700). According to certain illustrative examples, additional transparent layers having additional grating layers formed thereon may be stacked. As light passes through each grating element, it will be further modified to reach a final predetermined configuration.

In one example, light (714) is emitted from the active region (702) of a VCSEL formed within the optoelectronic substrate. This light propagates through the first transparent layer (704) to the first sub-wavelength grating element (720) formed within the first grating layer (710). The first sub-wavelength grating element (720) then alters the light according to the grating pattern of that first sub-wavelength grating element (720). In this example, the grating pattern of the first sub-wavelength grating element (720) slightly expands the beam of light.

After passing though the first sub-wavelength grating element (720), the light (716) propagates through a second transparent layer (706) formed on top of the first grating layer (710). This second transparent layer (706) essentially acts as a spacer. The light (716) propagates through the second transparent layer (706) until it reaches a second sub-wavelength grating element (722) formed within a second grating layer (712). This second sub-wavelength grating element (722) is designed to collimate the beam of light.

After passing through the second sub-wavelength grating element (722), the collimated light travels through a third transparent layer (708) placed adjacent to the second grating layer (712). In one example, the third transparent layer (708) is an optical transmission medium designed to propagate collimated light (718). In some cases, the third transparent layer (708) may be a detachable piece of equipment that is not manufactured onto the second grating layer (712). Rather, the third transparent layer (708) may be butted against the second grating layer (712) so as to allow the collimated light (718) to be coupled into the third transparent layer (708).

Additional transparent layers and grating layers may be used to form additional stacking layers. In one example, a first layer may split a beam into two collimated beams that are projected at two or more precise angles. The subsequent grating layer may include two sub-wavelength grating elements corresponding to the one sub-wavelength grating element of the first grating layer. Each of the two sub-wavelength grating elements of the second layer may straighten the collimated beams. A subsequent grating layer may then include two sub-wavelength grating elements to focus each of those beams into different optical transmission media that will be placed up against that final grating layer.

The sub-wavelength grating elements and stack configurations illustrated throughout this specification are not intended to be an exhaustive depiction of all configurations embodying principles described herein. Various other stack combinations may be used to perform desired optical functions. Additionally, a particular chip may include an array of sub-wavelength grating elements aligned with active regions of the optoelectronic components formed within the chip. Each of these sub-wavelength grating elements may vary according to design purposes.

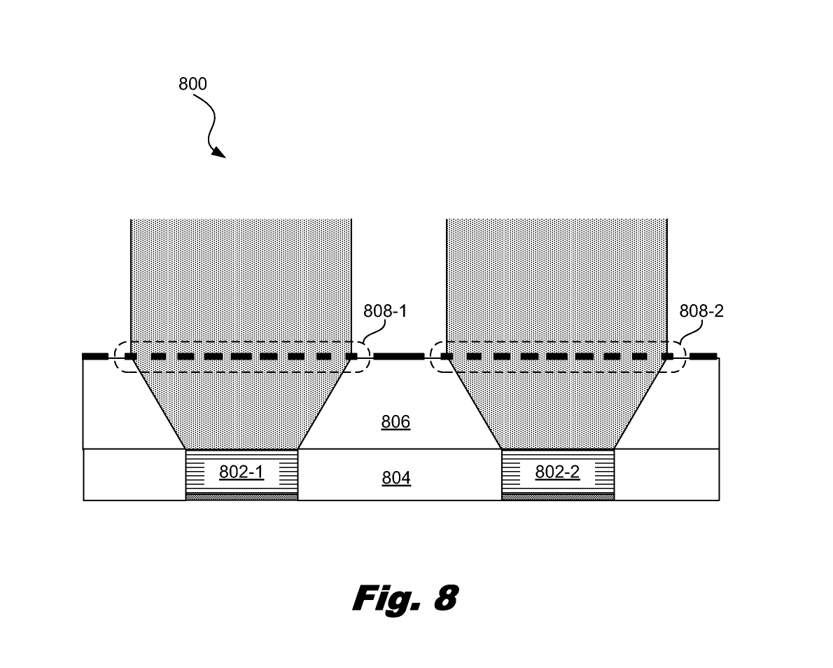

FIG. 8 is a diagram showing an illustrative integrated circuit chip (800) having multiple sub-wavelength grating elements (808) for multiple optoelectronic components (802). According to certain illustrative examples, an array of optoelectronic components (802) is formed within an optoelectronic substrate (804). The transparent layer (806) covers the array of optoelectronic components (802). An array of sub-wavelength gratings (808) is formed within a grating layer placed on the transparent layer (806). Each of the sub-wavelength gratings (808) is formed in alignment with an active region of an optoelectronic component (802). Moreover, each sub-wavelength grating element (808) may be designed to affect light from its corresponding optoelectronic component (802) in a different manner to satisfy various design purposes.

Forming an array of optoelectronic components (802) with corresponding sub-wavelength grating elements (808) provides a less costly, more compact integrated circuit. This is because no complicated lens systems are used. Rather, the optical elements are manufactured right onto the integrated circuit chip.

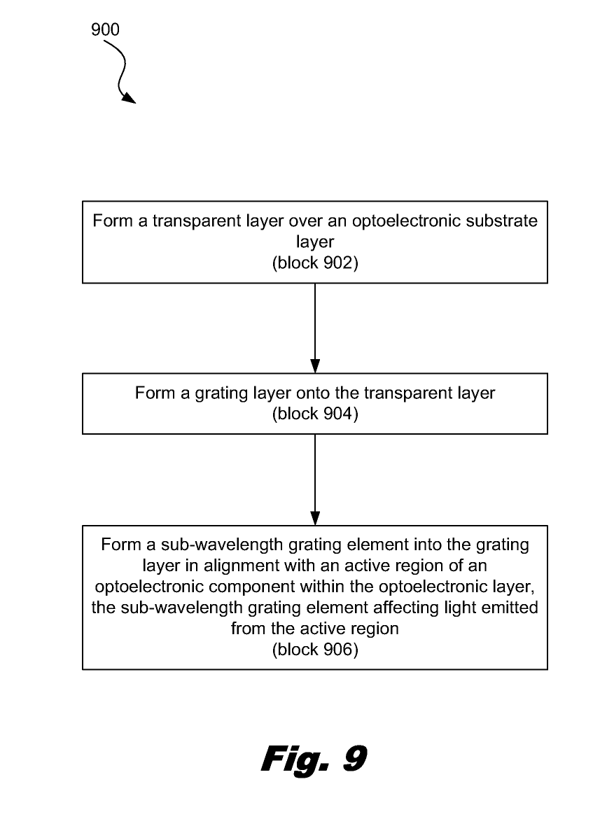

FIG. 9 is a flowchart showing an illustrative method for forming an integrated grating element. According to certain illustrative examples, the method includes forming (block 902) a transparent layer onto an optoelectronic substrate layer, forming (block 804) a grating layer onto the transparent layer, and forming (block 806) a sub-wavelength grating element into the grating layer in alignment with an active region of an optoelectronic component within the optoelectronic layer, the sub-wavelength grating element affecting light emitted from the active region.

In conclusion, through use of methods and systems embodying principles described herein, optical elements can be manufactured directly onto an integrated circuit chip having optoelectronic components formed thereon. Thus, light emitting from the optoelectronic components such as VCSELs can be focused into various optical transmission mediums or be configured for free space propagation without the use of complicated and costly lens alignment procedures. Additionally, light may be focused onto optoelectronic components such as photo-detectors without such costly lens alignment procedures.

The preceding description has been presented only to illustrate and describe examples of the principles described. This description is not intended to be exhaustive or to limit these principles to any precise form disclosed. Many modifications and variations are possible in light of the above teaching.

What is claimed is:

1. An integrated sub-wavelength grating element comprising:
a transparent layer formed over an optoelectronic substrate layer;
a sub-wavelength grating element formed into a grating layer disposed on said transparent layer in alignment with an active region of an optoelectronic component within said optoelectronic substrate layer, said sub-wavelength grating element affecting light passing between said active region and said sub-wavelength grating element.

2. The integrated grating element of claim 1, wherein said grating pattern comprises a two-dimensional, non-periodic variation of grating feature parameters to affect light in a predetermined manner.

3. The integrated grating element of claim 1, wherein said grating pattern is to cause said grating element to one of: collimate said light, focus said light, split said light, bend said light, and transmit said light.

4. The integrated grating element of claim 1, wherein said transparent layer comprises an oxide layer.

5. The integrated grating element of claim 1, further comprising:
multiple optoelectronic components formed in said optoelectronic substrate layer; and
multiple sub-wavelength grating elements formed into said grating layer, said multiple sub-wavelength grating elements in alignment with active regions of said optoelectronic components.

6. The integrated grating element of claim 1, further comprising, an additional transparent spacing layer placed adjacent to said grating layer, said additional transparent spacing layer comprising a second grating layer formed on a side of said transparent spacing layer opposing a side that is adjacent to said grating layer, said second grating layer comprising a second sub-wavelength grating element to be aligned with said active region.

7. The integrated grating element of claim 1, wherein said active region of said optoelectronic element substrate comprises one of: a Vertical Cavity Surface Emitting Laser (VCSEL) and a light sensing device.

8. A method for forming an integrated sub-wavelength grating element, the method comprising:
forming a transparent layer over an optoelectronic substrate layer;
forming a grating layer on said transparent layer;
forming a sub-wavelength grating element into said grating layer in alignment with an active region of an optoelectronic component of said optoelectronic layer, said sub-wavelength grating element affecting light passing between said grating element and said active region.

9. The method of claim 8, wherein said grating pattern comprises a two-dimensional, planar, non-periodic variation of grating feature parameters to affect light in a predetermined manner.

10. The method of claim 8, wherein said grating pattern is configured to one of: collimate said light, focus said light, split said light, bend said light, and transmit said light.

11. The method of claim 8, wherein said transparent layer comprises an oxide layer.

12. The method of claim 8, further comprising:
forming multiple optoelectronic components into said optoelectronic substrate layer; and
etching multiple sub-wavelength grating elements into said grating layer, said multiple sub-wavelength grating elements in alignment with active regions of said multiple optoelectronic components.

13. The method of claim 8, further comprising, placing an additional transparent spacing layer adjacent to said grating layer, said additional transparent spacing layer comprising a second grating layer formed on a side of said transparent spacing layer opposing a side that is adjacent to said grating layer, said second grating layer comprising a second sub-wavelength grating element to be aligned with said active region.

14. The method of claim 8, wherein said grating layers are to affect said light such that said light propagates through an optical transmission medium.

15. An integrated circuit chip comprising:
a Vertical Cavity Surface Emitting Laser (VCSEL) substrate layer comprising an array of VCSELs formed therein;
a planarizing transparent layer formed over said VCSELs; and
a grating layer comprising an array of sub-wavelength grating elements formed therein, said sub-wavelength grating elements being aligned with active regions of said array of VCSELs;
wherein, said sub-wavelength grating elements are to affect light emitted from said active regions.
